(19) United States
(12) Patent Application Publication
(10) Pub. No.: US 2026/0068723 A1
(43) Pub. Date: Mar. 5, 2026

(54) PASSIVE COMPONENTS ON MULTI-LAYER SUBSTRATES

(71) Applicant: TEXAS INSTRUMENTS INCORPORATED, Dallas, TX (US)

(72) Inventor: Vincy Ann DANGANAN, Pampanga (PH)

(21) Appl. No.: 18/821,879

(22) Filed: Aug. 30, 2024

(51) Int. Cl. H01L 23/498; H01L 21/48; H01L 21/56; H01L 23/00; H01L 23/31; H01L 25/16

(52) U.S. Cl. CPC H01L 23/49822; H10D 1/68

(57) ABSTRACT

A semiconductor package comprises a multi-layer substrate including multiple metal layers and a solid dielectric layer contacting the multiple metal layers. The multi-layer substrate includes first conductive terminals on a bottom surface of the multi-layer substrate, with the first conductive terminals coupled to the multiple metal layers. The multi-layer substrate includes second and third conductive terminals on a top surface of the multi-layer substrate opposing the bottom surface of the multi-layer substrate, the second and third conductive terminals coupled to the multiple metal layers. The package includes multiple metal members on the second conductive terminals, and a capacitor coupled to the multiple metal members, with the multiple metal members forming a gap between the capacitor and the multi-layer substrate. The package includes a semiconductor die on the top surface of the multi-layer substrate and bond wires coupled to the third conductive terminals. The package includes a mold compound.

### BACKGROUND

Semiconductor wafers are circular pieces of semiconductor material, such as silicon, that are used to manufacture semiconductor chips. Generally, complex manufacturing processes are used to form numerous integrated circuits on a single wafer. The formation of such circuits on a wafer is called fabrication. After wafer fabrication, the wafer is cut into multiple pieces, called semiconductor dies, with each die containing one of the circuits. The cutting, or sawing, of the wafer into individual dies is called singulation. An individual die is then coupled to a die pad and to conductive terminals, sometimes called “leads.” The resulting structure is subsequently covered with a mold compound to produce a package.

### SUMMARY

In examples, a semiconductor package comprises a multi-layer substrate including multiple metal layers and a solid dielectric layer contacting the multiple metal layers. The multi-layer substrate includes first conductive terminals on a bottom surface of the multi-layer substrate, with the first conductive terminals coupled to the multiple metal layers. The multi-layer substrate includes second and third conductive terminals on a top surface of the multi-layer substrate opposing the bottom surface of the multi-layer substrate, the second and third conductive terminals coupled to the multiple metal layers. The package includes multiple metal members on the second conductive terminals, and a capacitor coupled to the multiple metal members, with the multiple metal members forming a gap between the capacitor and the multi-layer substrate. The package includes a semiconductor die on the top surface of the multi-layer substrate and bond wires coupled to the third conductive terminals. The package includes a mold compound.

In examples, a method for manufacturing a semiconductor package comprises forming a multi-layer substrate by iteratively plating a metal layer, depositing a build-up film, and grinding the build-up film, the multi-layer substrate including multiple metal layers and a dielectric layer between the multiple metal layers, the dielectric layer composed of the build-up film, the multi-layer substrate having opposing top and bottom surfaces, each of the top and bottom surfaces including conductive terminals. The method includes plating first and second pairs of metal members on first and second pairs of the conductive terminals on the top surface, respectively. The method includes coupling first and second capacitors to the first and second pairs of metal members so as to form gaps between the first capacitor and the multi-layer substrate and between the second capacitor and the multi-layer substrate, respectively. The method includes coupling first and second semiconductor dies to the top surface and wire bonding the first and second semiconductor dies to a subset of the conductive terminals on the top surface, the subset of conductive terminals positioned along at least part of a perimeter of the top surface. The method includes covering the multi-layer substrate, the first and second pairs of metal members, the first and second capacitors, and the first and second semiconductor dies with a mold compound.

### BRIEF DESCRIPTION OF THE DRAWINGS

FIG. 1 is a block diagram of an electronic device containing passive components on a multi-layer substrate, in accordance with various examples.

FIG. 2 is a top-down view of a semiconductor package containing passive components on a multi-layer substrate, in accordance with various examples.

FIG. 3 is a bottom-up view of a semiconductor package containing passive components on a multi-layer substrate, in accordance with various examples.

FIG. 4 is a cross-sectional view of a semiconductor package containing passive components on a multi-layer substrate, in accordance with various examples.

FIG. 5 is a perspective view of a semiconductor package containing passive components on a multi-layer substrate, in accordance with various examples.

FIG. 6 is a flow diagram of a method for manufacturing a semiconductor package containing passive components on a multi-layer substrate, in accordance with various examples.

FIGS. 7-20C are a process flow for manufacturing a semiconductor package containing passive components on a multi-layer substrate, in accordance with various examples.

### DETAILED DESCRIPTION

Some semiconductor packages include multi-layer substrates. A multi-layer substrate is a substrate that includes multiple, horizontal, metal layers interconnected by vertical metal vias and covered at least in part by a dielectric (e.g., a build-up film) and that is not a printed circuit board (PCB). Because of their unique structures, multi-layer substrates provide various advantages, but the multi-layer substrates also present several disadvantages, including the lack of signal-filtering capabilities, the lack of ability to support high-speed applications, and inadequate power supply. Even if such capabilities were available, technical implementation challenges would still persist.

This disclosure describes various examples of a semiconductor package containing passive components coupled to a multi-layer substrate. More specifically, the semiconductor packages described herein include passive components, such as capacitors, coupled to the multi-layer substrates of the semiconductor packages. The passive components can provide the capabilities that multi-layer substrates presently lack, such as the signal-filtering capabilities, high-speed application support capabilities, and power supply capabilities that capacitors provide. Furthermore, the passive components are coupled to the multi-layer substrates using one or more metal members. Such a metal member physically distances a passive component from the multi-layer substrate by a gap that is specifically selected to provide various benefits. For example, the gap may be selected to facilitate mechanical isolation, meaning that the gap provides vibration damping to protect the passive component from mechanical stress. Similarly, the gap may be selected to provide strain relief, allowing the passive component to move slightly without subjecting the passive component to excessive mechanical stress, particularly on the solder joints coupling the passive component to the multi-layer substrate. The gap may mitigate parasitic capacitances between the passive component and the multi-layer substrate, which is particularly useful in high-frequency applications, and is also useful to mitigate signal coupling, noise, and distortion and to improve signal integrity. Similarly, electromagnetic interference is also reduced. The gap also facilitates thermal management, providing air circulation around the passive component and promoting heat dissipation.

In examples, a semiconductor package comprises a multi-layer substrate including multiple metal layers and a solid dielectric layer contacting the multiple metal layers. The multi-layer substrate includes first conductive terminals on a bottom surface of the multi-layer substrate, with the conductive terminals coupled to the multiple metal layers, and the multi-layer substrate further including second and third conductive terminals on a top surface of the multi-layer substrate opposing the bottom surface of the multi-layer substrate. The second and third conductive terminals are coupled to the multiple metal layers. The package also comprises multiple metal members on the second conductive terminals, and a capacitor coupled to the multiple metal members, with the multiple metal members forming a gap between the capacitor and the multi-layer substrate. The package also comprises a semiconductor die on the top surface of the multi-layer substrate, bond wires coupled to the semiconductor die and to the third conductive terminals, and a mold compound covering the multi-layer substrate, the multiple metal members, the capacitor, the semiconductor die, and the bond wires.

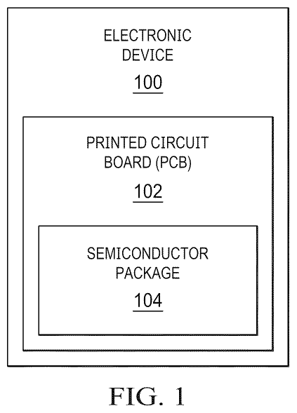

FIG. 1 is a block diagram of an electronic device 100 containing passive components on a multi-layer substrate, in accordance with various examples. The electronic device 100 may be any suitable type of device that may benefit from the inclusion of a semiconductor package having passive components on a multi-layer substrate. Such devices may include, for example, an automobile, an aircraft, a watercraft, a spacecraft, a video game console, an arcade video game unit, a smartphone, an entertainment device, an appliance, a laptop computer, a desktop computer, a tablet, a notebook, or any other suitable type of system or device. The electronic device 100 may include a PCB 102, and a semiconductor package 104, various examples of which are described herein, may be coupled to the PCB 102.

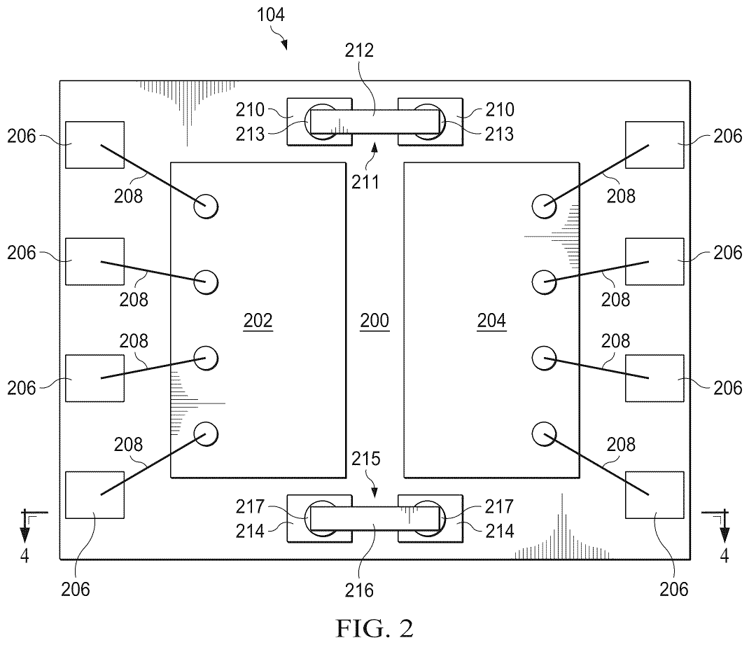

FIG. 2 is a top-down view of a semiconductor package containing passive components on a multi-layer substrate, in accordance with various examples. More specifically, FIG. 2 is a top-down view of portions of an example semiconductor package 104. The example semiconductor package 104 may include a multi-layer substrate 200, which, as described above, includes multiple, horizontal, metal layers interconnected by vertical metal vias and covered at least in part by a dielectric (e.g., a build-up film) and that is not a printed circuit board (PCB). The semiconductor package 104 also may include semiconductor dies 202 and 204 coupled to the multi-layer substrate 200. Although two semiconductor dies 202, 204 are shown, the semiconductor package 104 may include any number of semiconductor dies. In examples, the semiconductor dies 202, 204 are configured to operate in separate voltage domains. In examples, all semiconductor dies included in the semiconductor package 104 are configured to operate in separate voltage domains. In examples, two or more of the semiconductor dies (e.g., semiconductor dies 202, 204) are configured to operate in the same voltage domain. Each of the semiconductor dies 202, 204 may be configured to perform differing operations, similar operations, or the same operations. The multi-layer substrate 200 may include multiple conductive terminals (which may also be referred to herein as metal layers) 206 on a top surface of the multi-layer substrate 200, i.e., on a same surface to which the semiconductor dies 202, 204 are coupled. For example, the conductive terminals 206 may be arranged in rows or columns along one or more edges of the top surface of the multi-layer substrate 200, as FIG. 2 shows. The conductive terminals 206 may be composed of a suitable metal, such as copper, or a suitable alloy. In examples, the surfaces of the conductive terminals 206 that are visible in FIG. 2 are flush, or approximately flush (i.e., within 100 microns of being flush), with the top surface of the multi-layer substrate 200. Bond wires 208 are coupled to device sides of the semiconductor dies 202, 204 in and/or on which circuitry is formed (e.g., to bond pads on the semiconductor dies 202, 204), and to the conductive terminals 206. For example, the bond wires 208 may be coupled to the semiconductor dies 202, 204 by ball bonds, and the bond wires 208 may be coupled to the conductive terminals 206 by stitch bonds.

Multiple metal members 210, 214 may be coupled to the top surface of the multi-layer substrate 200, and more specifically, to conductive terminals on the top surface of the multi-layer substrate 200, as described in greater detail below. The semiconductor package 104 includes a pair of metal members 210 and a pair of the metal members 214. The metal members 210, 214 extend above the top surface of the multi-layer substrate 200, as described in greater detail below. Further, the metal members 210 are separated from each other by a gap 211, and the metal members 214 are separated from each other by a gap 215, as described in greater detail below. The metal members 210, 214 may be composed of a suitable metal, such as copper, or a suitable alloy.

A passive component 212 (e.g., a capacitor, inductor, resistor) has two terminals, each of the terminals coupled to a different one of the metal members 210 by solder joints 213. Similarly, a passive component 216 (e.g., a capacitor, inductor, resistor) has two terminals, each of the terminals coupled to a different one of the metal members 214 by solder joints 217. Accordingly, the passive component 212 straddles the gap 211, and the passive component 216 straddles the gap 215. The passive components 212, 216 are separated by a distance ranging from 125 microns to 150 microns, with a distance less than this range being disadvantageous because of the unacceptably high risk of damage to one or more of the passive components 212, 216 during the mounting process, and with a distance greater than this range being disadvantageous because of substantial increases in package size.

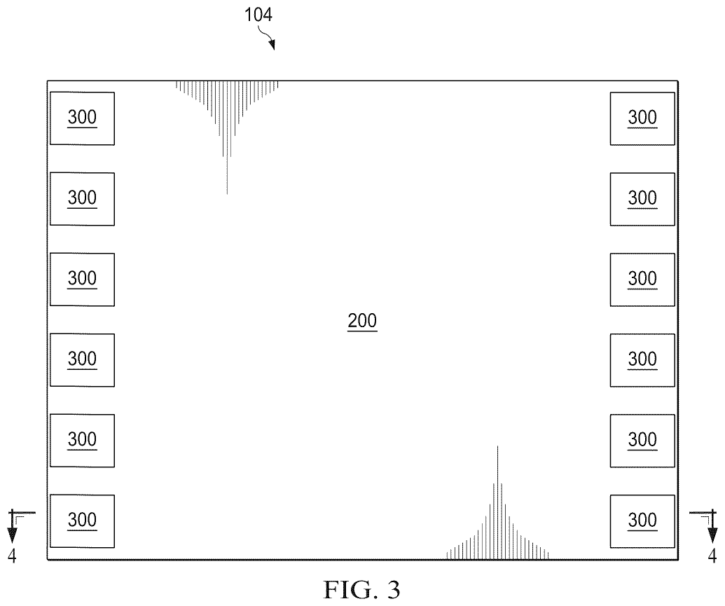

FIG. 3 is a bottom-up view of the semiconductor package 104, in accordance with various examples. The semiconductor package 104 may include the multi-layer substrate 200, as described above, and the bottom surface of the multi-layer substrate 200 (opposite to the top surface of the multi-layer substrate 200) includes multiple conductive terminals 300, as shown. The conductive terminals 300 may be arranged in rows or columns along one or more edges of the bottom surface of the multi-layer substrate 200. The conductive terminals 300 may be composed of any suitable metal, such as copper, or any suitable alloy. In examples, the surfaces of the conductive terminals 300 that are visible in FIG. 3 are flush, or approximately flush (i.e., within 100 microns of being flush), with the bottom surface of the multi-layer substrate 200.

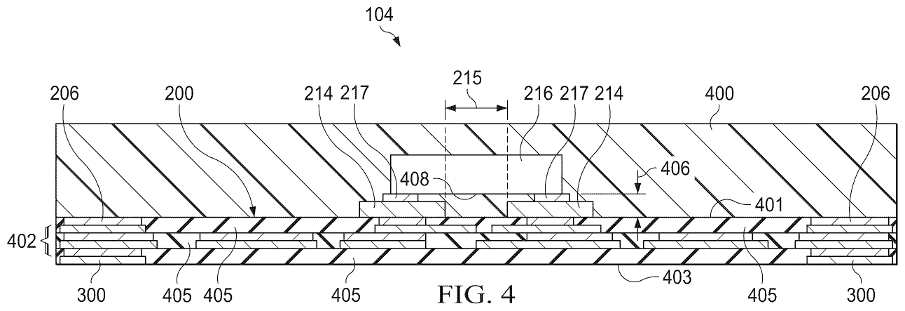

FIG. 4 is a cross-sectional view of the semiconductor package 104, in accordance with various examples. Specifically, FIG. 4 shows the multi-layer substrate 200 including the conductive terminals 206 exposed to a top surface 401 of the multi-layer substrate 200, conductive terminals 300 exposed to a bottom surface 403 of the multi-layer substrate 200, and a network of metal layers 402 within the multi-layer substrate 200, in between the top and bottom surfaces 401, 403 of the multi-layer substrate 200. The multi-layer substrate 200 may further include a dielectric 405, which may include a build-up film (e.g., an epoxy resin, a glass fiber reinforcement, and/or a filler material), such as AJINOMOTO® build-up film (ABF). The dielectric 405 contacts and covers various structures (e.g., one or more metal layers) within the multi-layer substrate 200. The network of metal layers 402 may have any suitable, application-specific arrangement or configuration to provide electrical signals between the top and bottom surfaces 401, 403 of the multi-layer substrate 200.

As shown, the metal members 214 extend vertically away from the top surface 401. The description provided herein of the metal members 214 applies in part or in whole to the metal members 210 (FIG. 2) as well. The metal members 214 are separated by the gap 215. The gap 215 ranges between 100 microns and 350 microns, with a gap 215 smaller than this range being disadvantageous because it results in poor airflow and heat dissipation, and with a gap 215 larger than this range being disadvantageous because it occupies an unacceptably large amount of space on the multi-layer substrate 200 and an unacceptably large amount of volume within the semiconductor package 104. The description of the gap 215 provided herein also applies in part or in whole to the gap 211 (FIG. 2).

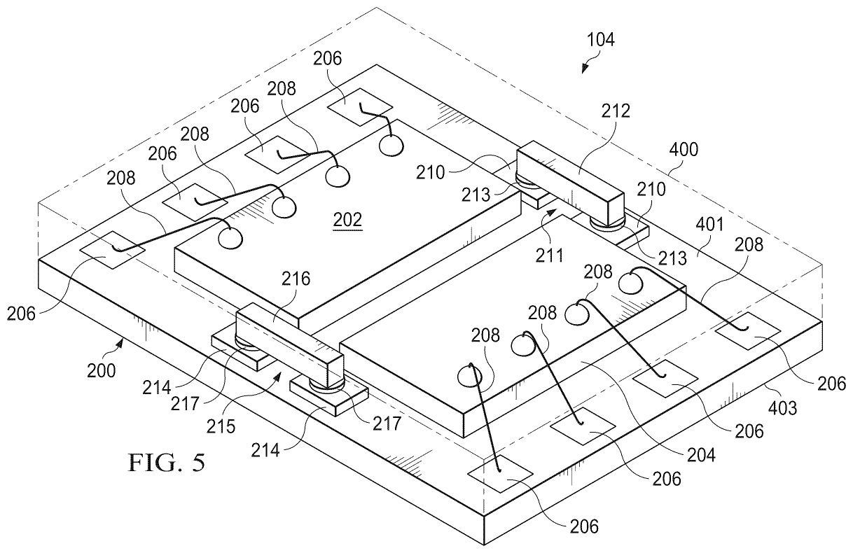

Further, as shown, the metal members 214 are sufficiently thick so as to form a gap 406 between the top surface 401 and a bottom surface 408 of the passive component 216. The total height of the gap 406 is composed of the thickness of the metal members 214 and the thickness of the solder joints 217. The height of the gap 406 ranges between 30 microns and 60 microns, with a gap 406 smaller than this range being disadvantageous because it results in poor airflow and heat dissipation, unacceptably high mechanical stress and strain, and multiple operational disadvantages (e.g., parasitic capacitances between the passive component 216 and the multi-layer substrate 200, signal coupling, noise, distortion, electromagnetic interference, etc.), and with a gap 406 larger than this range being disadvantageous because it occupies an unacceptably large amount of space on the multi-layer substrate 200 and an unacceptably large amount of volume within the semiconductor package 104. To achieve such a gap height, the thicknesses of the metal members 214 range from 20 microns to 50 microns, with excursions outside of this range having the negative consequences described above for falling outside of the prescribed range of heights of the gap 406. The descriptions provided herein of the gap 406 and thicknesses of the metal members 214 and solder joints 217 also apply in part or in whole to the metal members 210, the solder joints 213, and/or the gap between the bottom surface of the passive component 212 and the top surface of the substrate 200 (FIG. 2). A mold compound 400 covers the top surface 401 of the multi-layer substrate 200 and the structures of the semiconductor package 104 that are above the top surface 401 of the multi-layer substrate 200, such as the metal members 214, the solder joints 217, and the passive component 216, among others. FIG. 5 is a perspective view of the structures of FIGS. 2-4, in accordance with various examples.

The network of metal layers 402 facilitates electrical communication between the semiconductor dies 202, 204 and the passive components 212, 216. In this way, the semiconductor dies 202, 204 are able to use the passive components 212, 216. Depending on the type of passive components used, different advantages may be realized. In the case that the passive components 212, 216 are capacitors, the semiconductor dies 202, 204, and the semiconductor package 104 more generally, realizes numerous technical advantages. Such technical advantages may include signal-filtering capabilities, high-speed application support capabilities (e.g., by enhancing signal integrity, reducing noise, and stabilizing power supplies), and additional power supply capabilities (e.g., by providing stored charge as power to the semiconductor dies 202, 204).

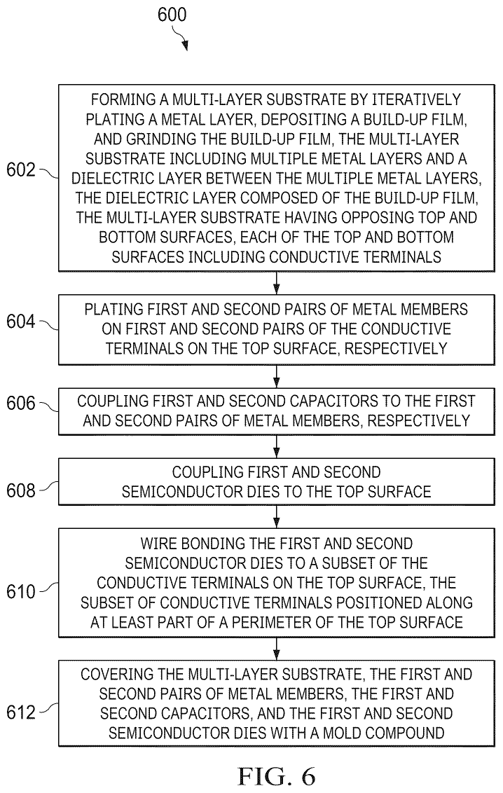

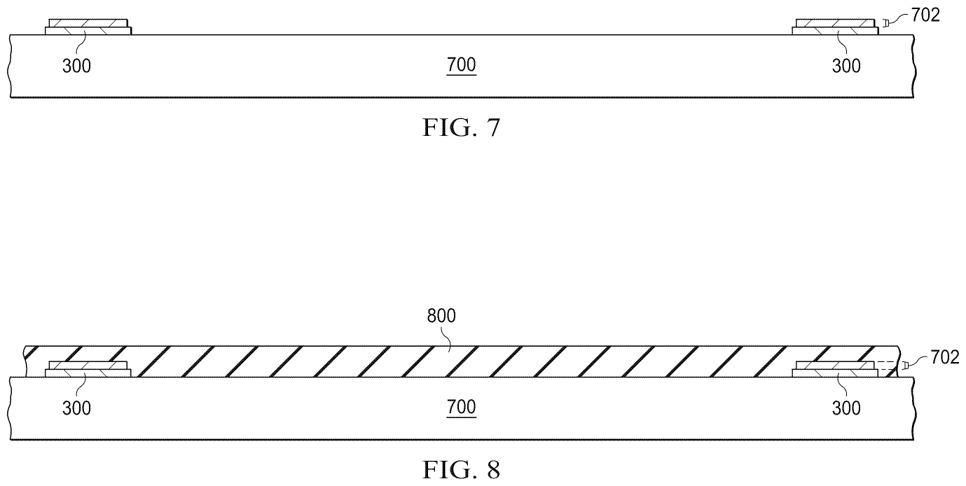

FIG. 6 is a flow diagram of a method 600 for manufacturing a semiconductor package (e.g., the semiconductor package 104) containing passive components on a multi-layer substrate, in accordance with various examples. FIGS. 7-20C are a process flow for manufacturing a semiconductor package (e.g., the semiconductor package 104) containing passive components on a multi-layer substrate, in accordance with various examples. Accordingly, FIGS. 6 and 7-20C are now described in parallel.

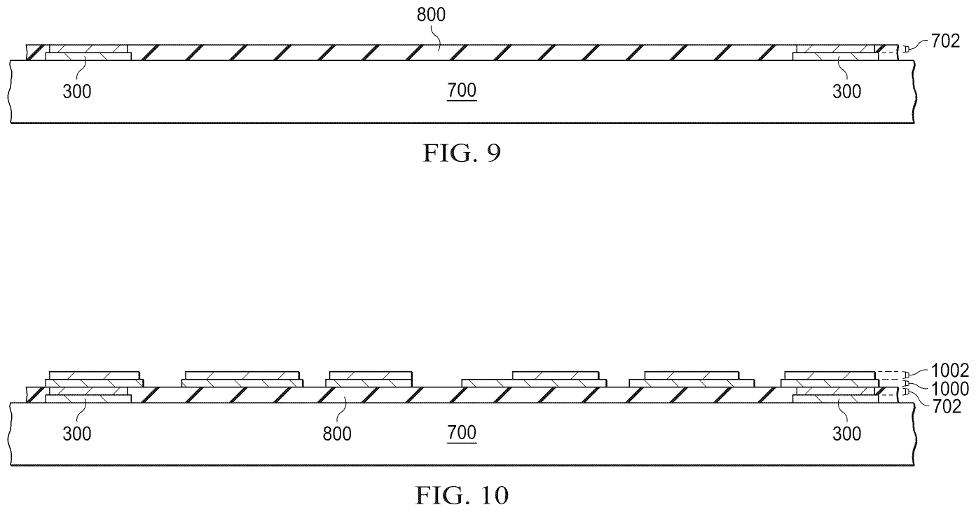

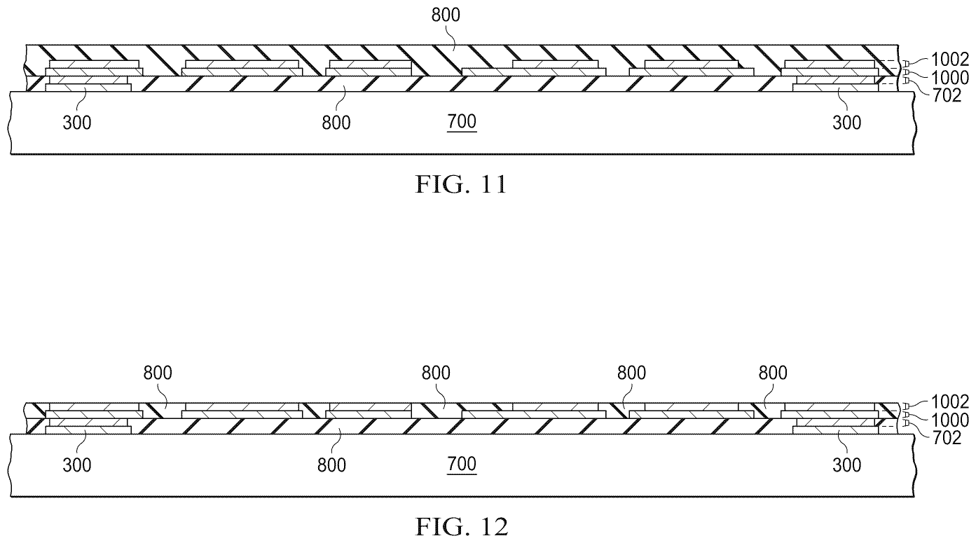

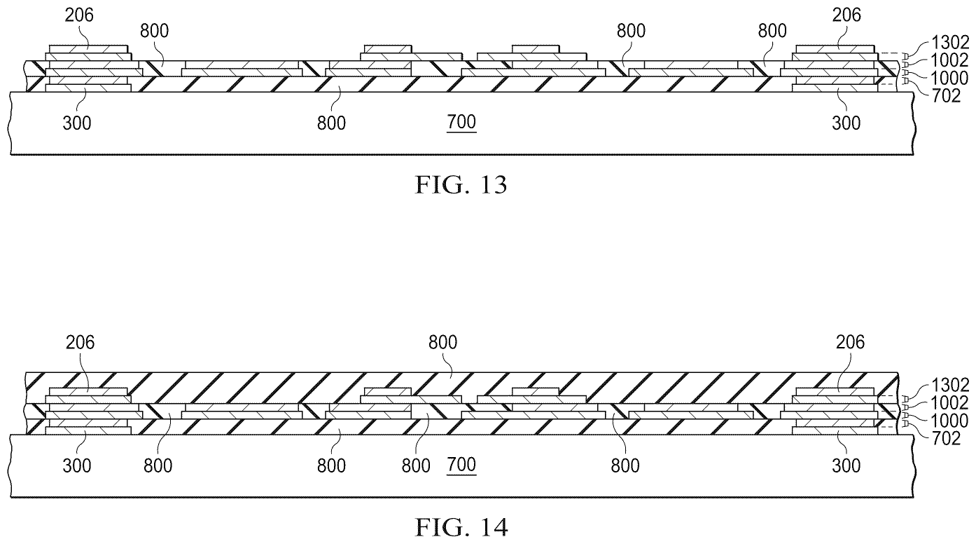

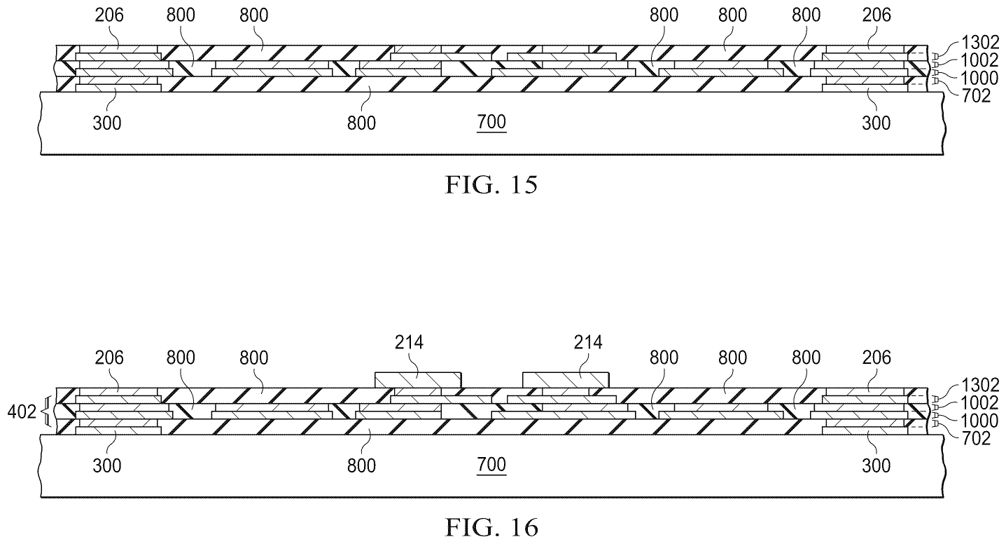

The method 600 may include forming a multi-layer substrate by iteratively plating a metal layer, depositing a build-up film, and grinding the build-up film (602). The multi-layer substrate may include multiple metal layers and a dielectric layer between the multiple metal layers (602). The dielectric layer may be composed of the build-up film (602). The multi-layer substrate may have opposing top and bottom surfaces, with each of the top and bottom surfaces including conductive terminals (602). FIG. 7 is a cross-sectional view of a base carrier 700, on which is plated a metal layer (or conductive terminals) 300, and a metal layer 702 is plated on the metal layer (or conductive terminals) 300. (In some cases, one or more of the metal layers in the multi-layer substrate described herein may be referred to as a vertical via, but for purposes of explanation, all such metal layers are referred to simply as metal layers.) As the cross-sectional view of FIG. 8 shows, a dielectric 800 (e.g., a build-up film, such as ABF, and similar or identical to dielectric 405) is applied to the metal layers 300, 702 and the base carrier 700. As the cross-sectional view of FIG. 9 shows, the dielectric 800 is thinned by grinding until the top surface of the metal layer 702 is exposed. The process is then repeated. As the cross-sectional view of FIG. 10 shows, a metal layer 1000 is plated on the metal layer 702 and on the dielectric 800, and a metal layer 1002 is plated on the metal layer 1000. Additional dielectric 800 is applied to the existing dielectric 800 and to the metal layers 1000, 1002, resulting in the structure shown in the cross-sectional view of FIG. 11. The dielectric 800 is subsequently thinned by grinding until the top surfaces of the metal layer 1002 are exposed, as the cross-sectional view of FIG. 12 shows. A metal layer 1302 is plated on the metal layer 1002 and the dielectric 800, and a metal layer (or conductive terminals) 206 is plated on the metal layer 1302, resulting in the structure shown in the cross-sectional view of FIG. 13. Additional dielectric 800 is applied to the existing dielectric 800 and to the metal layers 206, 1302, resulting in the structure shown in the cross-sectional view of FIG. 14. The dielectric 800 is then thinned by grinding until the top surfaces of the metal layer (or conductive terminals) 206 are exposed, as the cross-sectional view of FIG. 15 shows. This iterative process may be repeated any number of times, resulting in a total number of metal layers in the multi-layer substrate that is fewer than, the same as, or greater than those shown in the drawings. Further, the plating steps may be performed in any suitable manner to form an application-appropriate layout of metal layers in the network of metal layers 402.

The method 600 may include plating first and second pairs of metal members on first and second pairs of the conductive terminals on the top surface of the multi-layer substrate (604). FIG. 16 is a cross-sectional view of the structure of FIG. 15, except that metal members 214 have been plated on the top surface of the multi-layer substrate, and more specifically, on conductive terminals 206. The thicknesses of the metal members 214 (and the metal members 210 (FIG. 2)) may be as described above to achieve a specific gap 406 height or range of heights. Although not visible in the cross-sectional view of FIG. 16, the metal members 210 (FIG. 2) also are plated in a manner similar to that used to form the metal members 214.

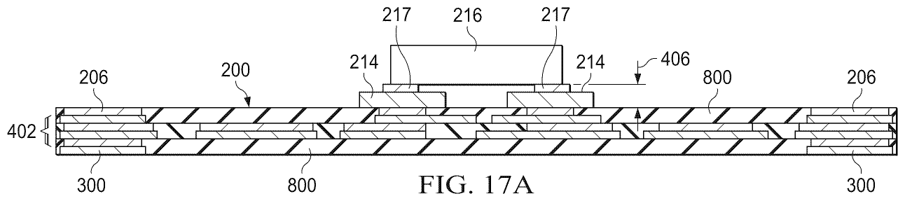

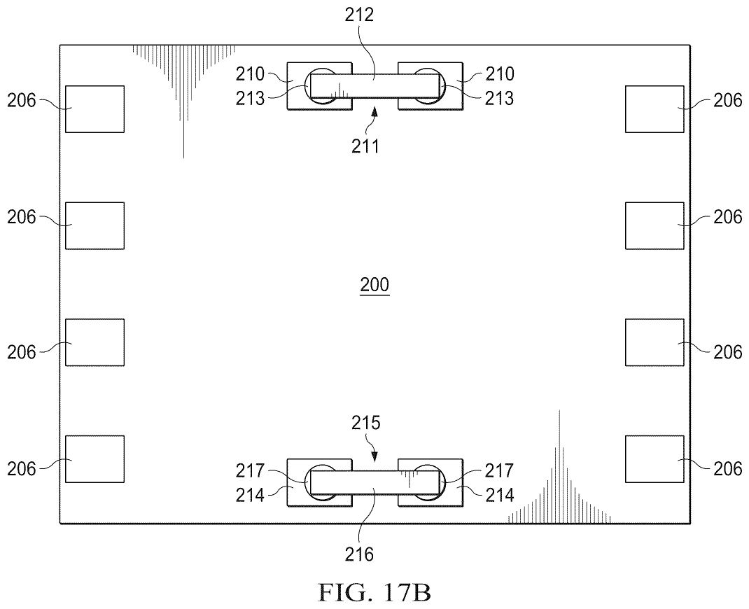

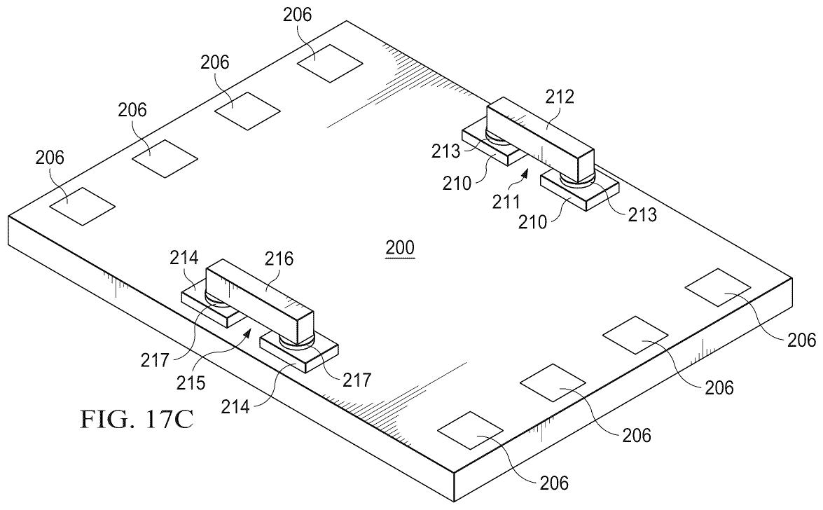

The method 600 may include coupling first and second passive components (e.g., capacitors, inductors, resistors) to the first and second pairs of metal members, respectively (606). FIG. 17A is a cross-sectional view of the structure of FIG. 16, except that the passive component 216 has been coupled to the metal members 214 using solder joints 217. The amount of solder applied to form the solder joints 217 should be carefully controlled to achieve a target height of the gap 406 (FIG. 4) required to achieve specific functional properties of the semiconductor package 104, such as heat dissipation, mechanical stress protection, and operational integrity, as described in detail above. FIG. 17B is a top-down view of the structure of FIG. 17A, in accordance with various examples. FIG. 17C is a perspective view of the structure of FIG. 17A, in accordance with various examples.

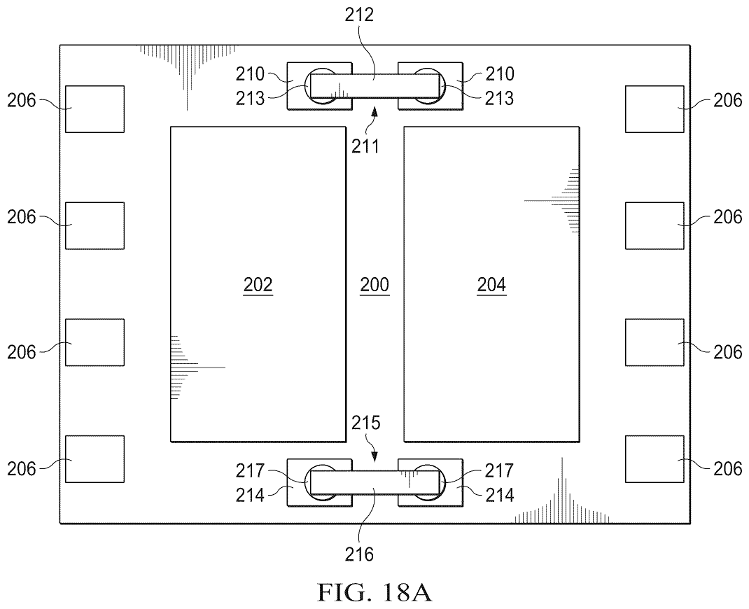

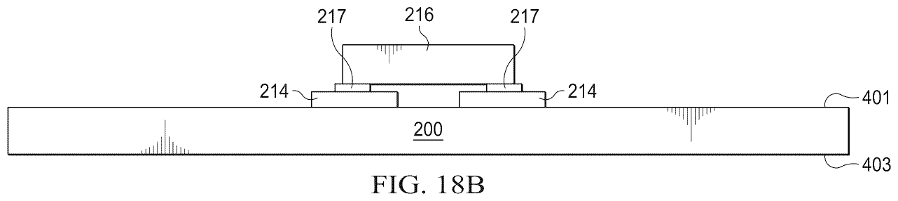

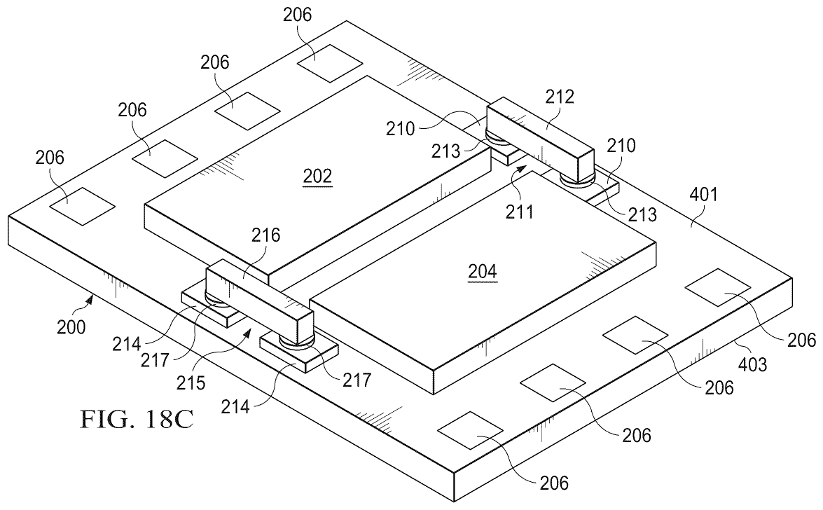

The method 600 may include coupling first and second semiconductor dies to the top surface of the multi-layer substrate (608). FIG. 18A is a top-down view of the structure of FIGS. 17A-C, except that the semiconductor dies 202, 204 have been coupled to the top surface 401 of the multi-layer substrate 200. For example, die attach material may be useful to establish such a connection. FIG. 18B is a profile view of the structure of FIG. 18A, in accordance with various examples. FIG. 18C is a perspective view of the structure of FIG. 18A, in accordance with various examples.

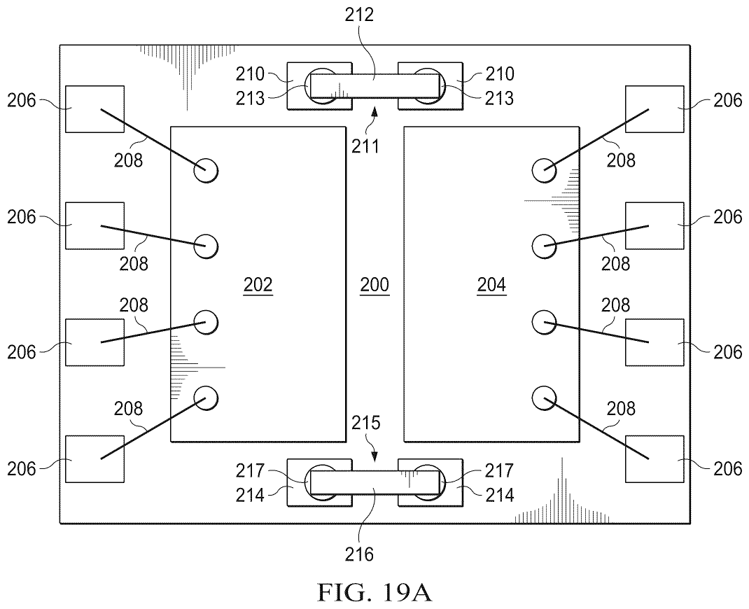

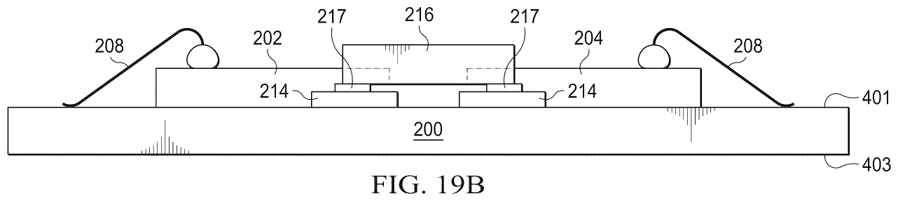

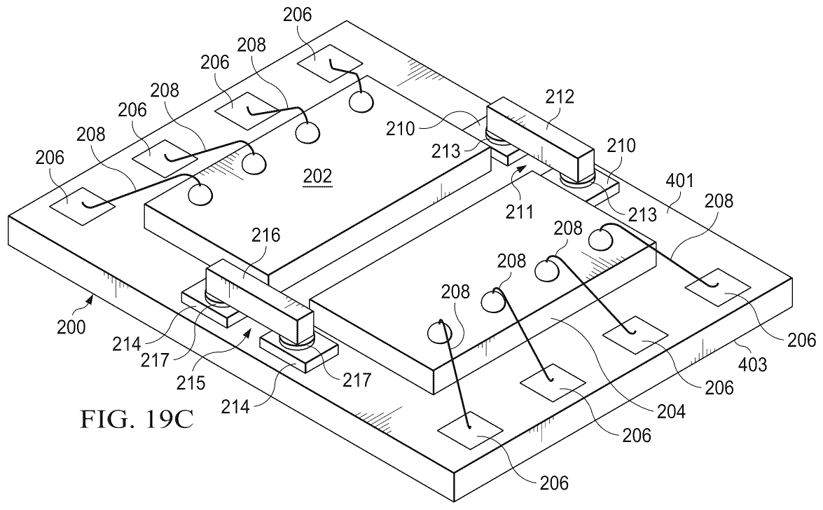

The method 600 may include wire bonding the first and second semiconductor dies to a subset of the conductive terminals on the top surface (610). The subset of the conductive terminals are positioned along at least part of a perimeter of the top surface (610). FIG. 19A is a cross-sectional view of the structure of FIGS. 18A-C, except that bond wires 208 are coupled from the semiconductor dies 202, 204 to various conductive terminals 206. FIG. 19B is a profile view of the structure of FIG. 19A, in accordance with various examples. FIG. 19C is a perspective view of the structure of FIG. 19A, in accordance with various examples.

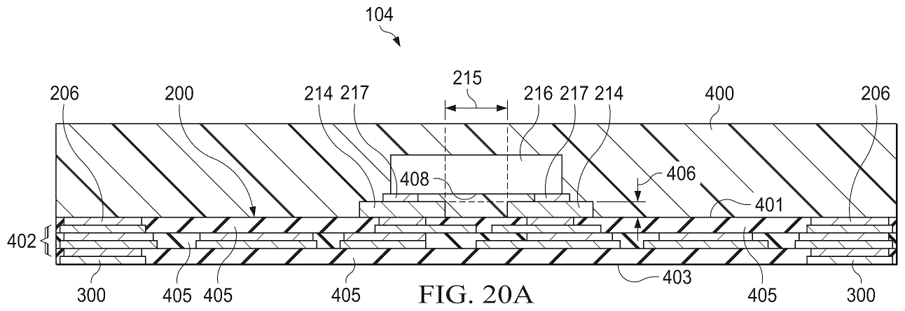

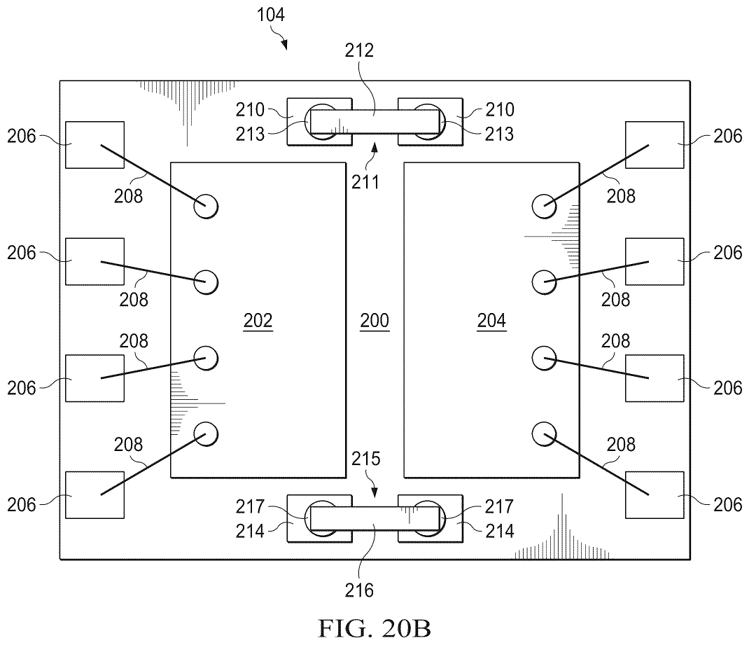

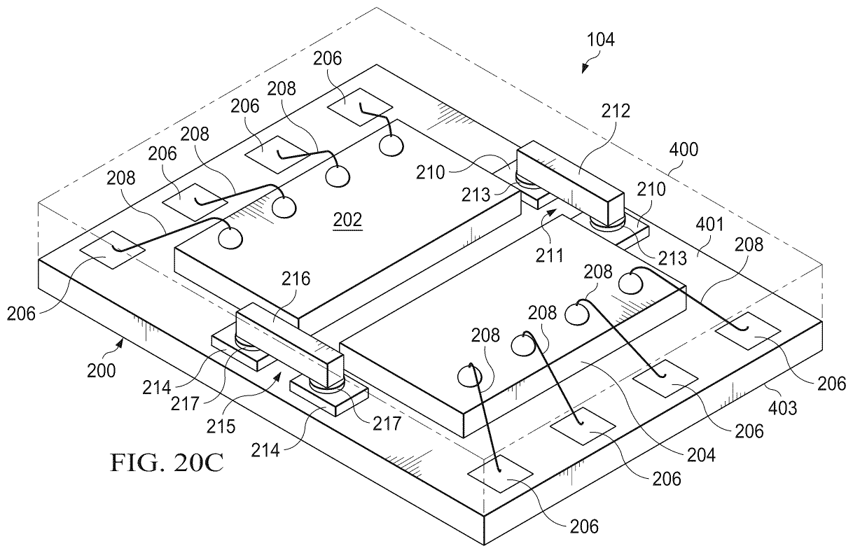

The method 600 may include covering the multi-layer substrate, the first and second pairs of metal members, the first and second capacitors, and the first and second semiconductor dies with a mold compound (612). FIG. 20A is a cross-sectional view of the structure of FIGS. 19A-C, except that the mold compound 400 has been applied to the various components of the semiconductor package 104. FIG. 20B is a top-down view of the structure of FIG. 20A, in accordance with various examples. FIG. 20C is a perspective view of the structure of FIG. 20A, in accordance with various examples.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

In this description, unless otherwise stated, “about,” “approximately” or “substantially” preceding a parameter means being within +/−10 percent of that parameter. Modifications are possible in the described examples, and other examples are possible within the scope of the claims.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device, or a semiconductor component.

What is claimed is:

1. A semiconductor package, comprising:
a multi-layer substrate including multiple metal layers and a solid dielectric layer contacting the multiple metal layers, the multi-layer substrate including first conductive terminals on a bottom surface of the multi-layer substrate, the first conductive terminals coupled to the multiple metal layers, the multi-layer substrate further including second and third conductive terminals on a top surface of the multi-layer substrate opposing the bottom surface of the multi-layer substrate, the second and third conductive terminals coupled to the multiple metal layers;
multiple metal members on the second conductive terminals;
a capacitor coupled to the multiple metal members, the multiple metal members forming a gap between the capacitor and the multi-layer substrate;
a semiconductor die on the top surface of the multi-layer substrate;
bond wires coupled to the semiconductor die and to the third conductive terminals; and
a mold compound covering the multi-layer substrate, the multiple metal members, the capacitor, the semiconductor die, and the bond wires.

2. The semiconductor package of claim 1, wherein the solid dielectric layer comprises a build-up film.

3. The semiconductor package of claim 2, wherein the build-up film comprises an epoxy resin, a glass fiber reinforcement, and a filler material.

4. The semiconductor package of claim 1, wherein the semiconductor die is configured to source power from the capacitor.

5. The semiconductor package of claim 1, wherein the capacitor is configured to filter a signal.

6. The semiconductor package of claim 1, wherein a metal member of the multiple metal members has a thickness ranging from 20 microns to 50 microns.

7. The semiconductor package of claim 1, wherein top surfaces of the second conductive terminals are approximately flush with the top surface of the multi-layer substrate, and wherein the multiple metal members are positioned above the top surface of the multi-layer substrate.

8. A semiconductor package, comprising:
a multi-layer substrate including multiple metal layers and a solid dielectric layer comprising a build-up film positioned between the multiple metal layers, the multi-layer substrate including a bottom surface and a top surface opposite the bottom surface, the bottom surface having multiple first conductive terminals coupled to the multiple metal layers and the top surface having multiple second conductive terminals coupled to the multiple metal layers, the multiple second conductive terminals positioned along at least part of a perimeter of the top surface;
a pair of semiconductor dies coupled to the top surface of the multi-layer substrate, the pair of semiconductor dies configured to operate in separate voltage domains;
first and second pairs of conductive terminals positioned on the top surface of the multi-layer substrate and on opposing sides of the pair of semiconductor dies;
a first capacitor coupled to the first pair of conductive terminals by way of a first pair of metal members forming a first gap between the first capacitor and the multi-layer substrate;
a second capacitor coupled to the second pair of conductive terminals by way of a second pair of metal members forming a second gap between the second capacitor and the multi-layer substrate;
bond wires coupling the pair of semiconductor dies to the multiple second conductive terminals; and
a mold compound covering the multi-layer substrate, the pair of semiconductor dies, the first and second pairs of conductive terminals, the first and second capacitors, and the bond wires.

9. The semiconductor package of claim 8, wherein the build-up film comprises an epoxy resin, a glass fiber reinforcement, and a filler material.

10. The semiconductor package of claim 8, wherein at least one of the semiconductor dies is configured to source power from at least one of the first and second capacitors.

11. The semiconductor package of claim 8, wherein at least one of the first and second capacitors is configured to filter a signal.

12. The semiconductor package of claim 8, wherein each of the first pair of metal members and each of the second pair of metal members has a thickness ranging from 20 microns to 50 microns.

13. The semiconductor package of claim 8, wherein top surfaces of the multiple second conductive terminals are approximately flush with the top surface of the multi-layer substrate, and wherein the first and second pairs of metal members are positioned above the top surface of the multi-layer substrate.

14. A method for manufacturing a semiconductor package, comprising:
forming a multi-layer substrate by iteratively plating a metal layer, depositing a build-up film, and grinding the build-up film, the multi-layer substrate including multiple metal layers and a dielectric layer between the multiple metal layers, the dielectric layer composed of the build-up film, the multi-layer substrate having opposing top and bottom surfaces, each of the top and bottom surfaces including conductive terminals;
plating first and second pairs of metal members on first and second pairs of the conductive terminals on the top surface, respectively;
coupling first and second capacitors to the first and second pairs of metal members so as to form gaps between the first capacitor and the multi-layer substrate and between the second capacitor and the multi-layer substrate, respectively;
coupling first and second semiconductor dies to the top surface;
wire bonding the first and second semiconductor dies to a subset of the conductive terminals on the top surface, the subset of conductive terminals positioned along at least part of a perimeter of the top surface; and
covering the multi-layer substrate, the first and second pairs of metal members, the first and second capacitors, and the first and second semiconductor dies with a mold compound.

15. The method of claim 14, wherein the build-up film includes an epoxy resin, a glass fiber reinforcement, and a filler material.

16. The method of claim 14, wherein at least one of the semiconductor dies is configured to source power from at least one of the first and second capacitors.

17. The method of claim 14, wherein at least one of the first and second capacitors is configured to filter a signal.

18. The method of claim 14, wherein each of the first pair of metal members and each of the second pair of metal members has a thickness ranging from 20 microns to 50 microns.

19. The method of claim 14, wherein top surfaces of the first and second pairs of conductive terminals are approximately flush with the top surface of the multi-layer substrate, and wherein the first and second pairs of metal members are positioned above the top surface of the multi-layer substrate.

20. The method of claim 14, wherein the first and second capacitors are separated by at least 125 microns.
